(19) United States
(12) Patent Application Publication
(10) Pub. No.: US 2026/0053037 A1
(43) Pub. Date: Feb. 19, 2026

(54) METHOD AND AN APPARATUS FOR FORMING AN ELECTRONIC DEVICE

(71) Applicant: STATS ChipPAC Pte. Ltd., Singapore (SG)

(72) Inventors: SeokBeom HEO, Incheon (KR); HeeSoo LEE, Incheon (KR); YeoJun YUN, Incheon (KR)

(21) Appl. No.: 19/300,680

(22) Filed: Aug. 15, 2025

(30) Foreign Application Priority Data
Aug. 16, 2024 (CN) 202411129758.5

(51) Int. Cl. H01L 23/00

(52) U.S. Cl. CPC H01L 24/81; H01L 24/75; H01L 2224/75102; H01L 2224/75251; H01L 2224/75252; H01L 2224/75651; H01L 2224/75985; H01L 2224/8109; H01L 2224/81097; H01L 2224/81098; H01L 2224/81192; H01L 2224/8122; H01L 2224/81815; H01L 2924/3511

(57) ABSTRACT

A method and an apparatus for forming an electronic device is provided. The method comprises: providing a substrate; disposing at least one electronic component on the substrate via a solder paste; applying microwave radiation to the substrate to reflow the solder paste; applying a vacuum pressure to the substrate to remove voids formed within the solder paste during the reflowing of the solder paste; solidifying the solder paste into solder bumps between the substrate and the at least one electronic component.

### TECHNICAL FIELD

The present application generally relates to semiconductor technology, and more particularly, to a method and an apparatus for forming an electronic device.

### BACKGROUND OF THE INVENTION

The semiconductor industry is constantly faced with complex integration challenges as consumers want their electronics to be smaller, faster and higher performance with more and more functionalities packed into a single device. Typically, electronic components are mounted onto a substrate via solder bumps. The formation of the solder bumps may include a reflowing process of a solder paste formed between the substrate and the electronic components, which enables efficient electrical connection between the substrate and the electronic components thereon. The reflowing process can be conducted by applying thermal convection heating to the entire device where the solder paste is heated and transformed into the solder bumps. However, due to mismatch in the coefficient of thermal expansion (CTE) between different materials within the device, the heating process by convection heat transfer may induce warpage issues, which may adversely affect device performance and following fabrication processes.

Therefore, a need exists for a method for forming an electronic device with reduced warpages and improved performance.

### SUMMARY OF THE INVENTION

An objective of the present application is to provide a method for forming an electronic device with reduced warpages and improved performance.

According to an aspect of the present application, a method for forming an electronic device is provided. The method comprises: providing a substrate; disposing at least one electronic component on the substrate via a solder paste; applying microwave radiation to the substrate to reflow the solder paste; applying a vacuum pressure to the substrate to remove voids formed within the solder paste during the reflowing of the solder paste; solidifying the solder paste into solder bumps between the substrate and the at least one electronic component

According to another aspect of the present application, an apparatus for forming an electronic device is provided. The apparatus comprising: a platform configured for placing a substrate, wherein the substrate is disposed with at least one electronic component via a solder paste; a microwave radiation source configured for applying microwave radiation to the substrate to reflow the solder paste; and a vacuum source configured for applying a vacuum pressure to the substrate to remove voids formed within the solder paste during the reflowing of the solder paste by the microwave radiation.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E illustrate various steps of a method for forming an electronic device according to a first embodiment of the present application.

FIG. 2 illustrates an apparatus for forming an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, electronic components generally mounted onto a substrate after a reflowing process of a solder paste which later forms solder bumps. Currently, the reflowing process may be conducted by applying thermal convection heating to the entire device where the solder bumps are formed, which may induce warpage issues due to nonuniform heating across the device. To address this issue, a new method for forming an electronic device is provided. The new method applies microwave radiation to reflow a solder paste between a substrate and at least one electronic component, which provides more uniform and rapid heating. Also, a vacuum pressure is further applied during the reflowing process of the solder paste to remove voids formed within the solder paste. As such, after the reflowing process, solder bumps with uniform structures and fewer defects can be formed, which enhances joint reliability between the substrate and the electronic component.

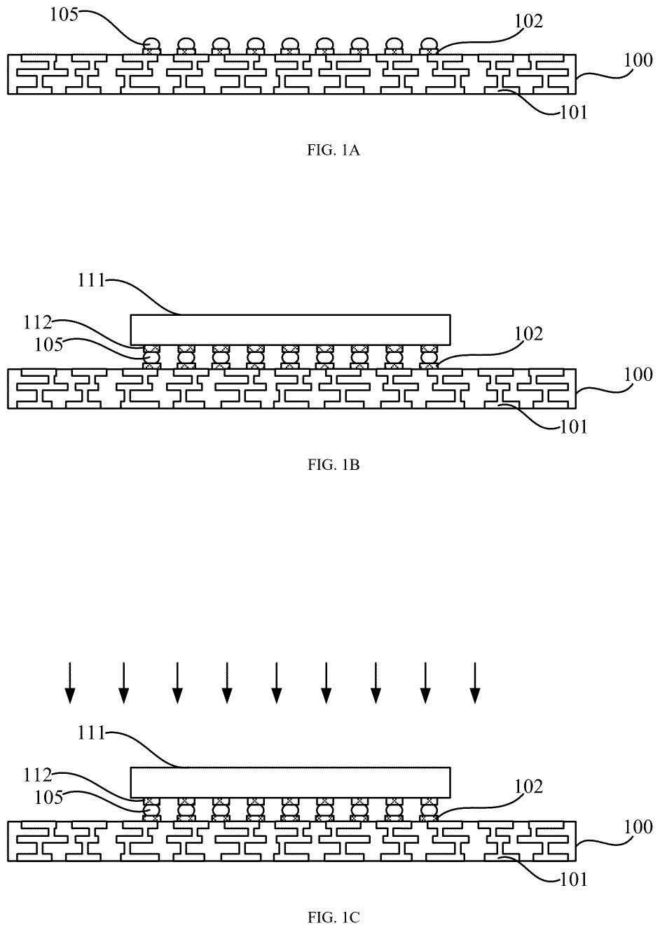

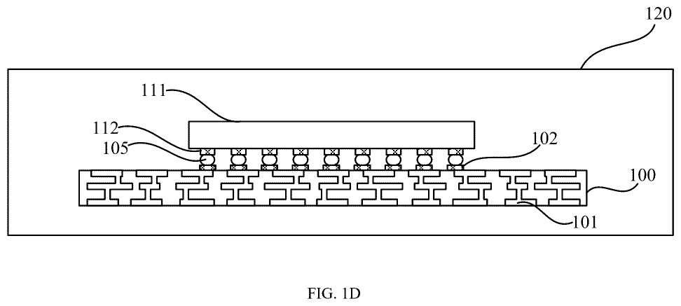

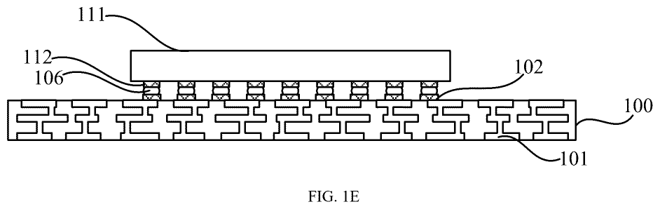

FIGS. 1A to 1E illustrate various steps of a method for forming an electronic device according to a first embodiment of the present application.

As shown in FIG. 1A, a substrate 100 is provided with embedded interconnect wires 101. The substrate 100 includes a front surface, which may serve as a platform where electronic component(s) can be mounted, and a back surface opposite to the front surface. The interconnect wires 101 may be formed between and through the substrate 100. Thus, the electronic component(s) and other structures on either one surface or both surfaces of the substrate 100 may be electrically coupled with each other to form an integrated electronic system. In some embodiments, a first set of conductive pads 102 can be formed on the front surface of the substrate 100 for the mounting of the electronic component(s). It also can be appreciated that the first set of conductive pads 102 may be exposed portions of interconnect wires 101 formed within the substrate 100.

In some embodiments, the substrate 100 includes at least a non-polar material, such as silicon, which is the main part of the material of the substrate 100. It should be noted that the substrate 100 may also contain a minor amount of polar materials. For example, in this embodiment, the substrate 100 may contain more than 99 wt. % of non-polar material(s) and less than 1 wt. % of polar materials, which may be helpful to improve structural and electrical performances of the substrate 100. In some other embodiments, the substrate 100 may contain less than 2 wt. %, 5 wt. % or 10 wt. % of polar materials.

Next, a solder paste 105 is attached on each of the first set of conductive pads 102 for the mounting of the electronic component(s). The solder paste 105 may include metal solder and flux. In some embodiments, the metal solder may include a metal material or a combination of metal materials. It can be appreciated that a combination of metal and non-metal materials may also be provided within the metal solder. To be more specific, the metal material(s) may be Al, Sn, Ni, Au, Ag, lead (Pb), bismuth (Bi), Cu, or combinations thereof. In some embodiments, the metal solder may include metal powders, for example, sintered metal powders. In some other embodiments, an adhesive material may be further provided to glue the metal powders. The adhesive material should be sticky enough to glue the metal powders together before, during and after a subsequent heating process of the solder paste 105. In other words, the adhesive material should not volatilize completely during the heating process of the solder paste 105. In addition, the adhesive material may include a thermal conductive material, which allows for an efficient convection heat transfer within the solder paste 105 during the heating process. In some alternative embodiments, the adhesive material may include a polar material, which further facilitates a heating process of the solder paste 105 when exposed to microwave radiation subsequently, since the adhesive material may absorb microwave energy and may thus be particularly heated.

Furthermore, the flux within the solder paste 105 may be used to facilitate a subsequent heating process of the solder paste 105, thereby enabling sufficient electrical connection between the substrate 100 and the electronic component(s) mounted thereon. The flux may include a significant amount of a polar material or polar materials, which can be particularly heated when exposed to microwave radiation. Furthermore, in some embodiments, the flux may include a polar material or polar materials having a degree of polarization higher than that of the metal solder included within the solder paste 105. Therefore, when exposed to microwave radiation, the flux may be heated to a higher temperature compared with the metal solder, which enables a sufficient convection heat transfer from the flux to the metal solder. In some embodiments, the flux may include one or more materials selected from the following group: nonylphenol ethoxylate, glyceryl monostearate, acid activator, water and mineral salt. In a preferred embodiment, the flux may include between 40 wt. % and 70 wt. % of nonylphenol ethoxylate, between 10 wt. % and 30 wt. % of glyceryl monostearate, between 3 wt. % and 10 wt. % of acid activator, between 3 wt. % and 10 wt. % of water, and between 4 wt. % and 15 wt. % of mineral salt.

In some embodiments, the flux may be coated onto surfaces, for example, bottom surfaces or whole spherical surfaces of the metal solder. In some other embodiments, the flux may be mixed within the metal solder to form an integrated solder paste mixture, which further enhances the convection heat transfer from the flux to the metal solder.

Next, as shown in FIG. 1B, at least one electronic component 111 is provided. In some embodiments, the electronic component(s) 111 may include various types of electronic modules, such as semiconductor chips, resistors, capacitors or the like. In an alternative embodiment, the at least one electronic component 111 may include a semiconductor package. It can be appreciated that the electronic component(s) 111 may be arranged and sized according to actual needs of the electronic device. In some embodiments, different types of the electronic components 111 may be included in a single electronic device, depending on actual needs. Furthermore, the at least one electronic component 111 includes at least a non-polar material. It can be appreciated that, similar to the substrate 100 which is illustrated in FIG. 1A, the electronic component 111 may contain a minor amount of polar materials, such as encapsulates or adhesives within the electronic component 111. For example, the electronic component 111 may contain more than 99 wt. %, 98 wt. %, 95 wt. % or 90 wt. % of non-polar material(s), and accordingly less than 1wt. %, 2 wt. %, 5 wt. % or 10 wt. %. of polar materials.

Next, the at least one electronic component 111 is disposed onto the front surface of the substrate 100. To be more specific, the at least one electronic component 111 may include a second set of conductive pads 112 on its back surface. Each of the second set of conductive pads 112 is aligned with one of the first set of conductive pads 102 with the solder paste 105 disposed therebetween. In some other embodiments, an additional solder paste may be attached on the second set of conductive pads 112. The at least one electronic component 111 may then be disposed on the front surface of the substrate 100 with the solder paste 105 and the additional solder paste disposed between the first and second set of conductive pads 102, 112.

Next, as shown in FIG. 1C, microwave radiation is applied to the substrate 100 to reflow the solder paste 105. In some embodiments, a microwave source is placed above the electronic component 111, and then microwave radiation is applied from the microwave source to the electronic component 111 to heat the solder paste 105. The electronic component 111 which may generally include non-polar material(s) may not absorb or may barely absorb the microwave energy, and thus the microwave can penetrate the electronic component 111 and reach the solder paste 105. In some other embodiments, the microwave source is placed at one or more lateral sides of the electronic component 111. The microwave radiation may be applied from the microwave source to the solder paste 105 from lateral sides. Therefore, the microwave may interact with the solder paste 105 more directly without first going through the electronic component 111, which may increase energy absorption efficiency for the solder paste 105. It can also be appreciated that the position where the microwave source is placed may vary according to the actual layout of the electronic device. For example, one or more microwave sources may be inclined for 30 degrees, 45 degrees, 60 degrees or any other suitable degrees with respect to the front surface of the substrate 100.

Still referring to FIG. 1C, when the solder paste 105 is exposed to the microwave radiation, the dipoles within the polar molecules of the flux within the solder paste 105 are sensitive to an electrical field of the microwave and may rotate to align themselves with a direction of the electrical field. The electrical field of the microwave is periodically changing, which may prompt the dipoles to rotate frequently. As a result, the dipoles may collide with each other when they attempt to follow the electrical field, which generates heat energy and results in a high temperature rise of the flux, e.g., to a temperature higher than a melting temperature of the metal solder within the solder paste 105. In addition, the metal solder within the solder paste 105, especially for the metal powders, may also absorb microwave energy to generate heat, which results in a moderate temperature rise of the metal solder. With the temperature rise of the flux, a part of the heated flux may volatilize first, and the heat generated in the flux may be convectively transferred to the metal solder, which brings about a further temperature rise of the metal solder. Then the temperature of the metal within the metal solder may rise over its melting temperature, which induces the metal to melt and enables the metal solder to be reshaped in a molten state.

During the microwave radiation process, the flux may be heated to reach a high reflow temperature to provide enough heat to the metal solder through convection, such that the metal solder may melt and wet on the first and second sets of conductive pads 102, 112. In a preferred embodiment, the reflow temperature of the solder paste may reach to a range between 200° C. and 240° C. In some other embodiments, the temperature of the solder paste may be even higher to achieve a more rapid reflow process. In some embodiments, the microwave radiation may be applied intermittently to control the temperature of the heated flux, e.g., the microwave radiation may be applied for a certain time duration such as 10 seconds to 2 minutes and then be suspended for another certain time duration such as 5 seconds to 30 seconds, and such cycle may be repeated for several times, depending on the reflowing of the solder paste 105. It can be appreciated that the certain time duration may be several seconds to several minutes, depending on the actual needs of the heating process, such as the specific composition of the flux and/or the metal solder, the amount of the metal solder, and/or the power of the microwave radiation. In some other embodiments, a temperature sensor, e.g., an infrared temperature sensor or an infrared image array, may be used to monitor the temperature of the flux or the metal solder within the solder paste 105, and may then provide the real-time temperature measurement(s) to a controller for the microwave source to adjust the power and/or duration of the microwave radiation, for example. In some preferred embodiments, the substrate 100 as well as the electronic component 111 mounted thereon may be placed in an atmosphere with a high ambient temperature to avoid that too much heat is transferred from the flux and/or metal solder to the substrate 100 and/or the electronic component 111 due to a significant temperature difference between them and the solder paste 105. For example, the ambient temperature may be 10° C. to 150° C., or preferably 10° C. to 50° C., or more preferably 10° C. to 30° C., lower than the reflow temperature of the metal within the solder paste 105.

Furthermore, in this embodiment, the microwave radiation is applied at variable frequencies during the microwave radiation step. By sweeping a range of frequencies rapidly, the microwave radiation process may increase the uniformity of microwave energy in comparison with a fixed-frequency microwave. The microwave radiation may be applied at a frequency ranging between 1 GHz and 10 GHz. The microwave source may be set at a power ranging between 100 W and 2000 W. In other embodiments, the microwave radiation may be applied at a frequency higher than 10 GHz or with a microwave source power higher than 1000 W, which allows for a more rapid temperature rise of the solder paste 105. In addition, the microwave radiation may last for a minimum duration, such as 1 minute to allow for sufficient heating of the metal solder and complete volatilization of the flux. It can also be appreciated that the frequency, power and duration of the microwave radiation may be selected according to actual needs of the reflowing process of the solder paste 105.

Since the molecules in non-polar materials are not sensitive to electrical fields of the microwaves, the substrate 100 and electronic component 111 may not be heated or may barely be heated by the microwave radiation when they are exposed to the microwave field together with the solder paste 105. In addition, the interconnect wires 101 which is embedded within the substrate 100 and metal layers which may be included within the electronic component 111 may reflect the microwave and may barely generate heat energy. In this way, the solder paste 105 is selectively heated by the microwave radiation. This heating mechanism may offer multiple advantages to the reflowing process of the solder paste 105. Firstly, instead of a traditional heating process applied to the whole electronic device, the selective heating of the solder paste 105 by microwave radiation may reduce the warpage issues of the substrate 100 and electronic component 111 since the substrate 100 and electronic component 111 are barely heated by the microwave radiation. Secondly, the microwave can penetrate the solder paste 105 to supply energy, and thus the heat can be generated throughout the solder paste 105 in a volumetric manner, which allows for a more uniform heat distribution from surfaces to interiors of the solder paste 105. Thirdly, the microwave induces molecular rotation without destroying molecular bonds due to low energy per photon, which may have little influence on the internal structures of the components of the electronic device. Fourthly, the microwave heating can be started and/or ended quickly, which may reduce the heating duration.

During the microwave radiation, gas in an environment and/or a residual gas of the vaporized flux may be trapped within the molten solder paste 105, thereby forming voids within the solder paste 105 which later transforms into solder bumps. The voids within the solder paste 105 can be removed by applying a vacuum pressure in a subsequent process, as elaborated below.

As shown in FIG. 1D, after the microwave radiation is applied, a vacuum pressure is applied to the substrate 100 quite shortly to continue the reflowing process of the solder paste 105. It should be noted that the reflowing process of the solder paste 105 includes a stage when the solder paste 105 is heated by the microwave radiation and an additional stage when the vacuum pressure is applied to the substrate 100. Here, applying the vacuum pressure to the substrate 100 refers to allowing the substrate 100 to be exposed to a vacuum atmosphere.

To be more specific, a vacuum chamber may be provided to accommodate the substrate 100 and structures thereon. The vacuum chamber may be fluidly coupled to a vacuum pump to provide a vacuum pressure within the vacuum chamber. In some embodiments, the substrate 100, the at least one electronic component 111 and the solder paste 105 therebetween are accommodated within the vacuum chamber to be exposed to the vacuum pressure. When the vacuum pressure is applied, the solder paste 105 is still at a high reflow temperature and in a molten state to continue the reflowing process of the solder paste 105. The molten solder paste 105 allows possibility of gas to escape therefrom, for example, under a vacuum atmosphere. At the same time, the vacuum pressure may create a pressure difference between an interior of the voids within the solder paste 105 and a vacuum environment outside the solder paste 105. As such, the gas trapped within the void may be expelled out of the solder paste 105. In addition, by removing the gas within the voids, heat may be more effectively transferred to the substrate 100 and the solder paste 105 without the hindering of the gas which has a relatively low thermal conductivity, thereby ensuring a uniform heat distribution across the solder paste 105. Furthermore, the vacuum environment around the solder paste 105 eliminates convective currents resulted from the gas flow, thereby reducing potential disturbance to heat transfer during the reflowing process of the solder paste 105 and provides a uniform heat distribution across the solder paste 105. As such, although the solder paste 105 absorbs microwave energy strongly and gets heated rapidly, the uniformity of the reflowing process may be improved and hotspots generated during the reflowing process may be reduced. Finally, as shown in FIG. 1E, the solder paste 105 is solidified into solder bumps 106 to form electrical joints between the substrate 100 and the at least one electronic component 111, thereby forming an electronic device. By applying the vacuum pressure, the reflowing process of the solder paste 105 may be conducted more uniformly and sufficiently. The solder bumps 106 can be formed with uniform structures and reduced void defects, which improves joint reliability between the at least one electronic component 111 and the substrate 100.

In some embodiments, the flux may volatilize completely, allowing the reflowed metal solder to form electrical joints. In some other embodiments, only a part of the flux may volatilize, and finally the remaining flux may be removed from the metal solder, for example, by a cleaning agent. In some alternative embodiments, finally the remaining flux and the metal solder may melt together to form electrical joints between the electronic component 111 and the substrate 100.

The reflowing process of the solder paste 105 within the vacuum environment may have a sufficient duration to ensure effective reflowing of the solder paste 105. In some embodiments, the vacuum pressure may be applied for a duration ranging from 30 seconds to 10 minutes. The vacuum pressure may be less than 5 mtorr to provide a sufficient vacuum environment, for example. Also, when the solder paste 105 is exposed to the vacuum environment, the solder paste 105 should keep at a reflow temperature, which ensures the solder paste 105 to keep in the molten state such that the voids within the solder paste 105 can be expelled. In some preferred embodiments, the reflow temperature may range from 200° C. to 240° C., thereby ensuring sufficient wetting of the solder paste 105, i.e., the metal solder material, on surfaces of the first and second sets of conductive pads 102, 112.

In some other embodiments, the vacuum chamber may be formed by attaching a top cover without a base onto at least a portion of the front surface of the substrate 100. Thus, the vacuum pressure can be provided within the vacuum chamber defined by the top cover and the front surface of the substrate 100. A smaller volume enables the vacuum chamber to achieve a required vacuum pressure more rapidly.

In some embodiments, when the vacuum pressure is applied to the substrate 100, the temperature of the solder paste 105 may keep at a range from 200° C. to 240° C. A heater may be provided to preserve heat energy and slow down a cooling speed of the solder paste 105, such that the solder paste 105 may be maintained at the reflow temperature within the vacuum environment, which may be approximately the same or slightly lower than the temperature of the solder paste 105 during the microwave radiation process. In some embodiments, a carrier with a heat transfer blocking top layer may be used instead of the heater, to avoid for fast cooling of the substrate 100 and the solder paste 105. In some embodiments, a duration that the vacuum pressure is applied to the substrate 100 may be longer than a duration that the microwave radiation is applied to the substrate 100. In this way, the voids within the solder paste 105 which are generated during the microwave radiation process can be removed sufficiently during the process when the vacuum pressure is applied. In some preferred embodiments, the duration that the vacuum pressure is applied to the substrate 100 may be two or three times the duration that the microwave radiation is applied to the substrate 100.

After the solder paste 105 is sufficiently reflowed, the vacuum pressure is no longer applied to the substrate 100, and the solder paste 105 may be cooled to a temperature lower than the reflow temperature, such that the solder paste 105 is solidified into solder bumps 106 to form electrical joints between the substrate 100 and the at least one electronic component 111. It can be appreciated that external gas may be introduced to raise the pressure that the substrate 100 and the reflowed solder paste 105 are exposed to, thereby ending the vacuum reflow process. In some preferred embodiments, a duration that the pressure is gradually increased after the vacuum reflow process may be the same or longer than (for example, two or three times) the duration that the vacuum pressure is applied to the substrate 100. Alternatively, the substrate 100 and the reflowed solder paste 105 may also be exposed to an atmosphere in the processing environment after the vacuum reflow process. In some other embodiments, the solder paste 105 may be cooled and solidified into solder bumps 106 when the vacuum pressure is applied to the substrate 100.

Referring to FIGS. 1A to 1E, the vacuum pressure is applied to the substrate 100 after the microwave radiation process to improve the reflowing process. In this way, the vacuum pressure is only applied at a later stage of the reflowing process, thereby saving energy consumption and enhancing process efficiency. In addition, the vaporized flux generated in the microwave radiation process may not be influenced by the vacuum environment, which guarantees the sufficient convection heat transfer from the flux to the metal solder.

In an alternative embodiment, the vacuum pressure is applied to the substrate 100 simultaneously when the microwave radiation is applied to reflow the solder paste 105. As such, the gas generated during the microwave radiation process may be instantly expelled and pumped out from the solder paste 105 in the vacuum environment. This may further reduce the gas trapped within the solder paste 105 during the reflowing process, and thus reduces the voids within the later solidified solder bumps 106. In addition, a duration of the reflowing process can be reduced, which improves process efficiency and saves costs. It can be appreciated that the vacuum pressure may be applied when the microwave radiation source is turned on. The vacuum pressure may also be applied after a certain period of time after the microwave radiation has already been applied.

Afterwards, an encapsulant layer may be formed on the substrate 100 to encapsulate the at least one electronic component 111 and the solder bumps 106, therefore forming an electronic package. In some other embodiments, the method for forming the electronic device may not include the process of forming the encapsulant layer.

In some embodiments, the method can be used in forming an electronic device with a reduced size and complex structures, such as a system-in-package (SIP) device with various electronic components. In some other embodiment, the electronic device can be applied in any devices which desire reduced warpage issues and improved reliability of the electrical joints. The electronic device may also be a double-sided electronic device, and accordingly, a back surface of the substrate may also serve as another platform where electronic component(s) may be mounted on via a solder paste. The solder paste on the front surface and the back surface of the substrate 100 may be reflowed by microwave radiation and within a vacuum environment to form electrical joints between the electronic component(s) and the substrate.

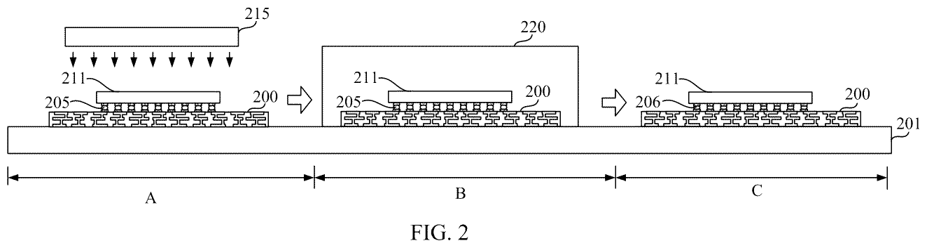

FIG. 2 illustrates an apparatus for forming an electronic device according to a second embodiment of the present application. In particular, a reflowing process of a solder paste 105 within the electronic device may be implemented using the apparatus. Details of a process of forming the electronic device may be similar to the method for forming the electronic device illustrated in FIGS. 1A to 1E.

As shown in FIG. 2, the apparatus may include three sequential zones, namely, a first zone A, a second zone B and a third zone C, which are used to implement a reflowing process of a solder paste 205 between a substrate 200 and at least one electronic component 211. The apparatus further includes a platform 201 configured for placing the substrate 200. The platform 201 is in a form of an integrated piece across the first zone A, the second zone B and the third zone C. In some embodiments, a main chamber may be provided to include all of the three zones or even more additional zones as desired, which may prevent contaminants from entering into the apparatus, thereby protecting the substrate 200 and structures thereon during the reflowing process.

In some embodiments, the first zone A is configured for applying microwave radiation to the substrate 200 via a microwave radiation source 215 to reflow the solder paste 205. The microwave radiation source 215 is arranged within the first zone A, for example, above the platform 201.

In some embodiments, during a microwave radiation process, an atmosphere in which the substrate 200 and the solder paste 205 are disposed may have a ambient temperature between 80° C. and 120° C. In some preferred embodiments, the platform 201 may be or include a heater which generates additional heat energy. The additional heat energy may raise the ambient temperature of the atmosphere during the microwave radiation process to alleviate heat dissipation. Also, since the platform 201 is in direct contact with the substrate 200, the additional heat energy can be convectively transferred to the substrate 200 and thus to the solder paste 205. This enables the solder paste 205 to be heated through a hybrid heating mechanism which incorporates the direct microwave heating and the convection heat transferred from the platform 201, thereby achieving a higher reflowing efficiency and a lower energy demand from the microwave radiation source 215. Moreover, with a lower microwave radiation energy applied from the microwave radiation source 215, overall heat generated within the formed device may be reduced, which may prevent or alleviate a burning effect caused by excessive microwave radiation energy. In addition, since a bottom part of the solder paste 205 with less exposure to the microwave radiation may receive more heat energy which is convectively transferred from the platform 201, the solder paste 205 may be reflowed in a more uniform and controlled way with fewer defects.

In some more preferred embodiments, the platform 201 may include a polar material, a combination of polar materials, or a combination of polar and non-polar materials, which can be heated by microwave radiation. In addition, the platform 201 may include thermal conductive material(s), which allows for sufficient convection heat transfer from the platform 201 to the substrate 200 and the solder paste 205 as well as alleviation of heat dissipation in the reflowing process of the solder paste 205 after the platform 201 is heated by microwave radiation. In some embodiments, a significant portion (e.g., greater than 50 wt. %, 60 wt. %, 70 wt. %, 80 wt. %, 90 wt. %, 95 wt. % or 99 wt. %) of the platform 201 is formed of polar material(s), which offers a better heating performance when exposed to microwave radiation. To be more specific, the platform 201 may include at least one polar material selected from a group of silicon carbide, graphite, charcoal with polarity and carbon with polarity. In some other embodiments, the platform 201 may include a non-polar base coated with polar material(s) or distributed with polar materials(s), which may lower the requirement on materials of the platform 201 and achieve a better mechanical support and a reduced cost during the reflowing process of the solder paste 205, if appropriate materials for the non-polar base are used. Particularly, the non-polar base may include a silicon wafer or silicon powders, and the polar coating may include at least one polar material selected from a group of silicon carbide, graphite, charcoal with polarity or carbon with polarity.

In these embodiments, when the microwave radiation is applied, the platform 201 may also be exposed to the microwave radiation, where the microwave radiation may penetrate the electronic component 211 and the substrate 200, and finally reach the platform 201. Thus, an excess amount of microwave radiation energy which cannot be absorbed by the solder paste 205 may be collected by the platform 201 and converted into heat, which, in turn, helps for the heating and reflowing of the solder paste 205. In some embodiments, the platform 201 may include at its bottom side a film or a plate which can reflect microwave upward. During the microwave radiation process, the reflected microwave may again penetrate the platform 201 and generate heat there, or even penetrate the platform 201 and reach the solder paste 205 again to heat and reflow the solder paste 205.

The second zone B is configured for applying vacuum pressure to the substrate 200 via a vacuum source to remove voids within the solder paste 205. The vacuum source may include a vacuum pump. The second zone B further includes a vacuum chamber 220 which is fluidly connected with a vacuum pump configured for providing a vacuum atmosphere within the vacuum chamber 220. The vacuum chamber 220 is used to accommodate the substrate 200 and provide a vacuum environment to the substrate 200. In some other embodiments, a heater may be disposed within the second zone B to heat the substrate 200 disposed on the platform 201, preserve heat energy and slow down a cooling speed of the solder paste 205, such that the solder paste 205 may be maintained at the reflow temperature within the vacuum environment.

The third zone C is configured for cooling the solder paste 205 and solidifying the solder paste 205 into solder bumps 206. In some embodiments, the third zone C may include a cooling component to facilitate the cooling of the solder paste 205, such as a radiator on the platform 201, a fan adjacent to the substrate 200 or an air conditioner. In some preferred embodiments, a cooling chamber is arranged in the third zone C to accommodate the substrate 200, thereby cooling the solder paste 205 by controlling the solder paste 205 at a relatively low temperature within the cooling chamber.

When forming an electronic device, the substrate 200 with structures thereon is first disposed on the platform 201 within the first zone A. The microwave radiation source 215 applies the microwave radiation to the substrate 200 to heat and reflow the solder paste 205. Next, the substrate 200 is transported into the second zone B, for example, into the vacuum chamber 220 where the vacuum pressure is applied by a vacuum pump to remove the voids within the solder paste 205 and continue the reflowing process. In some embodiments, the first zone A and the second zone B may be close to each other such that the substrate 200 may be rapidly transported into the vacuum chamber 220 in the second zone B when the solder paste 205 is still at a high reflow temperature and in a molten state. Next, after a vacuum reflowing process within the second zone B, the substrate 200 may be transported to the third zone C to cool the solder paste 205 and solidify the solder paste 205 into the solder bumps 206.

In some embodiments, a conveyor may extend through the first zone A, the second zone B and the third zone C. During the reflowing process, the conveyor is used for transporting the substrate 200 from the first zone A through the second zone B to the third zone C. The conveyor may include a belt or a carrier on a rail to transport the substrate 200 with a controlled speed. It can also be appreciated that the apparatus may not include a conveyor and the substrate 200 may be transported by a manual operation.

In some other embodiments, the apparatus may not include the third zone C. The substrate 200 and the solder paste 205 may be cooled and solidified within the second zone B with or without the vacuum pressure.

In some other embodiments, the vacuum pressure is applied to the substrate 200 simultaneously when the microwave radiation is applied to reflow the solder paste 205. In these cases, the first zone A and the second zone B illustrated in FIG. 2 may be combined into one reflowing chamber. The reflowing chamber may include the microwave radiation source 215 and be fluidly connected to the vacuum pump. When the substrate 200 is within the reflowing chamber, the microwave radiation is applied to the substrate 200 and the vacuum pressure is applied to the substrate 200 to reflow the solder paste 205.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a substrate;
disposing at least one electronic component on the substrate via a solder paste;
applying microwave radiation to the substrate to reflow the solder paste;
applying a vacuum pressure to the substrate to remove voids formed within the solder paste during the reflowing of the solder paste; and
solidifying the solder paste into solder bumps between the substrate and the at least one electronic component.

2. The method of claim 1, wherein the vacuum pressure is applied to the substrate when the solder paste is being reflowed.

3. The method of claim 1, wherein the vacuum pressure is applied to the substrate when the solder paste is at a reflow temperature ranging from 200° C. to 240° C.

4. The method of claim 1, wherein applying a vacuum pressure comprises:
applying the vacuum pressure for a duration ranging from 30 seconds to 10 minutes.

5. The method of claim 1, wherein the solder paste comprises metal and flux.

6. The method of claim 1, wherein solidifying the solder paste into solder bumps comprises:
cooling the solder paste to a temperature lower than a reflow temperature of the solder paste.

7. The method of claim 1, wherein applying a vacuum pressure to the substrate is performed after applying microwave radiation to the substrate.

8. The method of claim 1, wherein applying a vacuum pressure to the substrate is performed simultaneously with applying microwave radiation to the substrate.

9. An apparatus for forming an electronic device, the apparatus comprising:
a platform configured for placing a substrate, wherein the substrate is disposed with at least one electronic component via a solder paste;
a microwave radiation source configured for applying microwave radiation to the substrate to reflow the solder paste; and
a vacuum source configured for applying a vacuum pressure to the substrate to remove voids formed within the solder paste during the reflowing of the solder paste by the microwave radiation.

10. The apparatus of claim 9, wherein the solder paste comprises metal and flux.

11. The apparatus of claim 9, wherein the vacuum pressure is applied to the substrate when the solder paste is at a reflow temperature ranging from 200° C. to 240° C.

12. The apparatus of claim 9, wherein the vacuum source is further configured for applying the vacuum pressure for a duration ranging from 30 seconds to 10 minutes.

13. The apparatus of claim 9, wherein the platform comprises:
a first zone associated with the microwave radiation source, wherein the microwave radiation source is configured for applying the microwave radiation to the substrate when the substrate is in the first zone;
a second zone associated with the vacuum source, wherein the vacuum source is configured for applying the vacuum pressure to the substrate when the substrate is in the second zone; and
a third zone for cooling the solder paste and solidifying the solder paste into solder bumps.

14. The apparatus of claim 13, wherein the platform further comprises:
a conveyor extending through the first zone, the second zone and the third zone, wherein the conveyor is configured for transporting the substrate from the first zone through the second zone to the third zone.

15. The apparatus of claim 9, wherein the platform comprises:
a chamber associated with the microwave radiation source and the vacuum source, wherein when the substrate is within the chamber, the microwave radiation is applied to the substrate and the vacuum pressure is applied to the substrate.

16. The apparatus of claim 9, wherein the platform further comprises a heater configured for heating the substrate disposed on the platform.

17. The apparatus of claim 9, wherein the platform comprises at least a polar material, and the platform is configured for absorbing microwave radiation to heat the substrate disposed on the platform.
